(19) United States
(12) Patent Application Publication
(10) Pub. No.: US 2017/0288047 A1
(43) Pub. Date: Oct. 5, 2017

(54) Shallow-Trench Semi-Super-Junction VDMOS Device and Manufacturing Method Therefor

(71) Applicant: WUXI CHINA RESOURCES HUAJING MICROELETRONICS CO., LTD., Wuxi (CN)

(72) Inventors: Hongwei Zhou, Wuxi (CN); Xiaoru Sun, Wuxi (CN); Mengbo Ruan, Wuxi (CN)

(73) Assignee: WUXI CHINA RESOURCES HUAJING MICROELETRONICS CO., LTD, Wuxi (CN)

(21) Appl. No.: 15/323,106

(22) PCT Filed: Dec. 31, 2014
(86) PCT No.: PCT/CN2014/095928

§ 371 Date: Dec. 30, 2016

(30) Foreign Application Priority Data
Oct. 15, 2014 (CN) 201410547047.X

(51) Int. Cl. H01L 29/78; H01L 29/66; H01L 29/06

(52) U.S. Cl. CPC H01L 29/7802; H01L 29/0634; H01L 29/66712

(57) ABSTRACT

A shallow-trench semi-super-junction VDMOS device and a manufacturing method thereof are disclosed. According to an example of the present invention, the shallow-trench semi-super-junction VDMOS device includes: a substrate of a first conduction type; a first epitaxial layer over the substrate; a second epitaxial layer over the first epitaxial layer; two trench regions on both sides of the second epitaxial layer and extending from an upper surface to a bottom of the second epitaxial layer; a third epitaxial layer of a second conduction type formed in each of the trench regions; a fourth epitaxial layer over the second epitaxial layer; and well regions implanted from both sides of the upper surface of the fourth epitaxial layer and connected with the third epitaxial layers in the two trench regions. The present invention gives consideration to the cost of technical process and the convenience of production. At the same time, due to the existence of the semi-super-junction structure, the forward conduction resistance of the VDMOS device is drastically reduced and the capability of current conduction per unit area is enhanced.

### CROSS REFERENCE TO RELATED APPLICATIONS

The present patent application is a US National Stage of International Application PCT/CN2014/095928, filed on Dec. 31, 2014, designating the United States, and claiming the priority of Chinese patent application No. 201410547047.X entitled “Shallow-Trench Semi-Super-Junction VDMOS Device and Manufacturing Method Thereof” filed on Oct. 15, 2014 by the applicant Wuxi China Resources Huajing Microelectronics Co., Ltd., which is incorporated herein by reference in its entirety.

### TECHNICAL FIELD

The present invention relates to the field of a semiconductor device and a manufacturing process thereof, particularly to a shallow-trench semi-super-junction Vertical Double-diffused Metal Oxide Semiconductor (VDMOS) device and a manufacturing method thereof.

### BACKGROUND

VDMOS device is a power semiconductor device with advantages of both a bipolar transistor and a common MOS device. As compared to the bipolar transistor, it has a fast switching speed, a small switching loss, a high input impedance, a small driving power, a good frequency characteristics, a high transconducting linearity, no secondary breakdown with the bipolar power device and a large safety operation area. Therefore, the VDMOS device is an ideal power semiconductor device for either switching application or linear application.

For a VDMOS device, one of its important indices is the conduction resistance. With the development of VDMOS devices, their structures are improved continuously to reduce conduction resistance as much as possible and thereby to improve their capability of conducting current.

A prior-art VDMOS device structure is shown in FIG. 1, with a N-type VDMOS device as an example, which includes:

a substrate including a body layer 101 and an epitaxial layer 102 over the body layer 101, wherein the body layer 101 includes a drain region, and the body layer 101 and the epitaxial layer 102 are N-type doped;

a first body region 103 and a second body region 104 located in the epitaxial layer 102, which are of the same doping state, namely P-type doping; and

a first source region 106 in the first body region 103 and a second source region 105 in the second body region 104, the first source region 106 and the second source region 105 are of the same doping state, namely N-type doping.

For a traditional VDMOS, with the increase of breakdown voltage, due to the low doping content and large thickness of the epitaxial layer, the conduction resistance will be large, which is the well-known “Si limit” that the conduction resistance increases with the withstand voltage in a 2.5 power relationship. That is, the conduction resistance increases rapidly with the increase of withstand voltage. At the same time, its forward conduction resistance is very high, resulting in that a large chip area may be required. As can be seen from the above, traditional VDMOS devices suffer a high conduction resistance.

### SUMMARY

In view of this, the present invention provides a shallow-trench semi-super-junction VDMOS device and a manufacturing method thereof to address the technical problems with VDMOS devices of conventional structures such as too large forward conduction resistance and weak capability of conducting current per unit area.

A shallow-trench semi-super-junction VDMOS device includes:

a substrate of a first conduction type;

a first epitaxial layer over the substrate of the first conduction type, wherein the first epitaxial layer has a same conduction type with the substrate of the first conduction type;

a second epitaxial layer over the first epitaxial layer, wherein the second epitaxial layer has a same conduction type with the first epitaxial layer;

two third epitaxial layers extending from an upper surface of the second epitaxial layer to a bottom of the second epitaxial layer, wherein the two third epitaxial layers are disposed with an interval; and the third epitaxial layers have a conduction type opposite to that of the second epitaxial layer;

a fourth epitaxial layer over the second epitaxial layer, wherein the fourth epitaxial layer has a same conduction type with the second epitaxial layer;

two well regions implanted from an upper surface of the fourth epitaxial layer and connected with the two third epitaxial layers, wherein the well regions have a same conduction type with the third epitaxial layers;

a first source region and a second source region of the first conduction type over the two well regions;

a source metal layer on an upper surface of the first source region and the second source region;

a drain metal layer under the substrate of the first conduction type;

a gate region between the first source region and the second source region and over the fourth epitaxial layer, and a gate metal layer on an upper surface of the gate region.

Further, the first epitaxial layer has a resistivity of 5-20 Ohm·centimeter; the second epitaxial layer has a resistivity of 2-10 Ohm·centimeter; the third epitaxial layer in the trenches has a resistivity of 2-10 Ohm·centimeter; and the fourth epitaxial layer has a resistivity of 2-10 Ohm·centimeter.

Further, an upper surface of the second epitaxial layer is flush with an upper surface of the third epitaxial layers.

A manufacturing method of a shallow-trench semi-super-junction VDMOS device is provided and the manufacturing method may comprise:

providing a substrate of a first conduction type;

forming a first epitaxial layer over the substrate of the first conduction type, wherein the first epitaxial layer has a same conduction type with the substrate of the first conduction type;

forming a second epitaxial layer on the first epitaxial layer, wherein the second epitaxial layer has a same conduction type with the first epitaxial layer;

inscribing two trench regions which extends from an upper surface of the second epitaxial layer to a bottom of the second epitaxial layer, wherein the two trench regions are disposed with an interval,

forming a third epitaxial layer of a second conduction type in each of the two trenches, wherein the third epitaxial layer has a conduction type opposite to that of the second epitaxial layer;

forming a fourth epitaxial layer over the second epitaxial layer, wherein the fourth epitaxial layer has a same conduction type with the second epitaxial layer;

forming two well regions which are implanted from an upper surface of the fourth epitaxial layer and connected with the two third epitaxial layers in the trenches, wherein the well regions have a same conduction type with the third epitaxial layers;

forming a first source region and a second source region of the first conduction type over the two well regions;

forming a gate region between the first source region and the second source region and over the fourth epitaxial layer;

forming a drain metal layer under the substrate of the first conduction type;

forming a gate metal layer over the gate region;

forming a source metal layer over each of the first source region and the second source region.

Further, the first epitaxial layer has a resistivity of 5-20 Ohm·centimeter; the second epitaxial layer has a resistivity of 2-10 Ohm·centimeter; the third epitaxial layers in the trenches have a resistivity of 2-10 Ohm·centimeter; and the fourth epitaxial layer has a resistivity of 2-10 Ohm·centimeter.

Further, the trenches have a width of 0-10 μm and a depth of 0-30 μm.

Further, when a part of the third epitaxial layers formed in the trenches is beyond an upper surface of the second epitaxial layer, chemical mechanical polishing or chemical etching may be performed to this part, such that the upper surface of the second epitaxial layer is flush with the upper surface of the third epitaxial layers.

Preferably, a method for forming the well regions may comprise: implanting impurity ions of a same conduction type with the trenches over the trenches by using a photoresist as a barrier layer on the fourth epitaxial layer, and then performing a thermally annealing to form the well regions.

The present invention relates to the field of semiconductor technology and in particular discloses a shallow-trench semi-super-junction VDMOS device and a manufacturing method thereof. With the present invention, a shallow trench region is introduced into a conventional VDMOS structure in which an epitaxial layer of a certain conduction type and a proper resistivity is filled and the epitaxial layer only remains in the trench by chemical mechanical polishing (CMP) or chemical etching. Then, an epitaxial layer of a conduction type opposite to the above is grown, impurity ions of the same conduction type with the epitaxial layer in the trench are implanted over the epitaxial layer in the trench by using a photoresist as a barrier layer on the epitaxial layer of the opposite conduction type, and a well region may be formed after thermal annealing. After a certain thermal process, the well region may be connected with the epitaxial layer in the trench such that the original VDMOS of the conventional structure may become a semi-super-junction structure. In the present invention, an epitaxial layer of a certain conduction type is filled in a shallow trench and connected with a well region of the same conduction type thereon to form a pillar. The depth of the pillar is much shallower than that of a conventional super-junction device, and therefore it is called a semi-super-junction. As compared to a conventional super-junction VDMOS device, it gives consideration to both the cost of technical process and the convenience of manufacturing. At the same time, due to the existence of the semi-super-junction structure, it is possible to realize an enhanced strength of electric field per unit area, namely an enhanced voltage endurance capability. Therefore, it is possible to use epitaxy of lower resistivity, drastically reduce the internal resistance of conduction resistance, drastically reduce the forward conduction resistance and have a stronger capability of conducting current per unit area.

### BRIEF DESCRIPTION OF DRAWINGS

Further description will be presented below with reference to accompanying drawings, in which,

FIG. 1 is a structure diagram of a VDMOS in prior art;

FIG. 2 is a structure diagram of a shallow-trench semi-super-junction VDMOS device provided according to an embodiment of the present invention;

FIG. 3 is a flow chart of a manufacturing method of a N-type shallow-trench semi-super-junction VDMOS device provided according to an embodiment of the present invention; and

FIGS. 3A-3F are sectional views of the shallow-trench semi-super-junction VDMOS device in steps of the manufacturing method of VDMOS device provided according to an embodiment of the present invention.

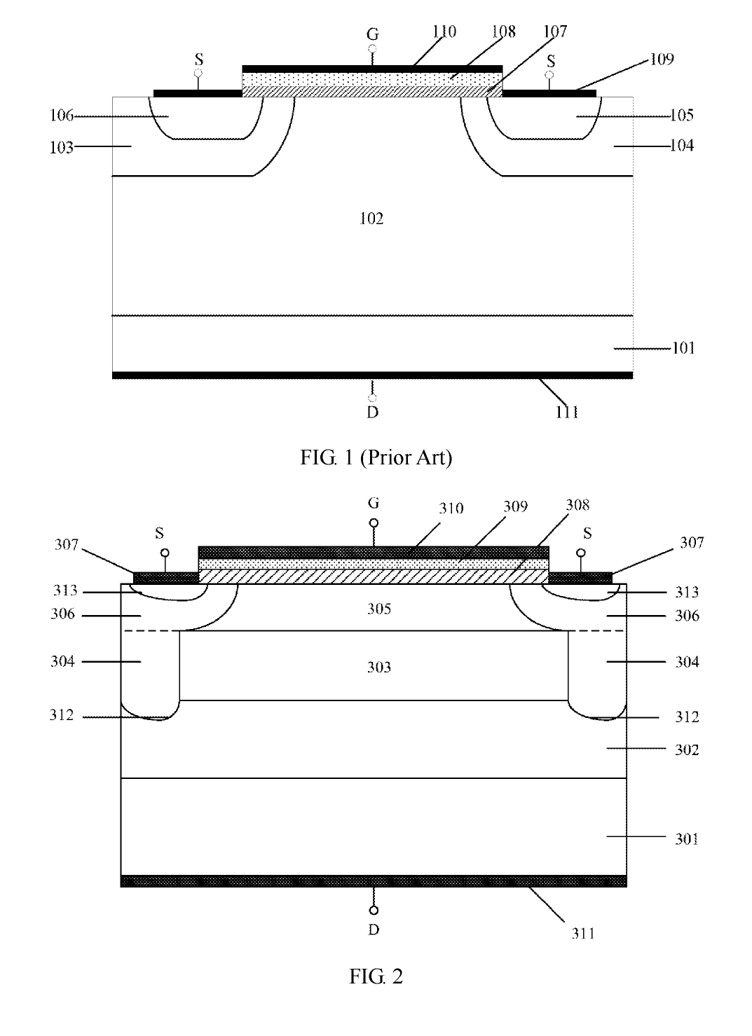

### DETAILED DESCRIPTION

In order to make the above-mentioned objects, features and advantages of the present invention clearer and more understandable, specific implementations of the present invention will be described in detail below with reference to accompanying drawings.

In the following description, many specific details are set forth to facilitate thoroughly understanding the present invention. However, the present invention may also be implemented in other ways different from those described herein. Those skilled in the art may make similar generalizations without departing from the spirit of the present invention. Therefore, the present invention is not limited by the specific embodiments disclosed below.

As described in the background, conduction resistance of a traditional VDMOS is limited by the Si limit as the withstand voltage increases, that is, the conduction resistance increases rapidly with the increase of withstand voltage. And in order to prevent breakdown of the resistance region, the lateral dimension of the device cannot be too small, which further leads to a large footprint of device cells, resulting in a low utilization ratio of substrate surface. For the super-junction VDMOS device, although the conduction resistance is reduced, the manufacturing process is complex and cannot be applied widely.

At present, in VDMOS devices, N-type VDMOS devices are used most widely. The present invention will be explained herein with respect to a strip-like cell structure of a N-type shallow-trench semi-super-junction VDMOS device and a manufacturing method thereof as an embodiment. It is to be noted, the present invention is not limited to the strip-like cell structure of the N-type shallow-trench semi-super-junction VDMOS device and the manufacturing method thereof, and is equally applicable to strip-like cell structure of other types of VDMOS devices.

According to an embodiment of the present invention, a shallow-trench semi-super-junction VDMOS device is provided and has a structure as shown in FIG. 2 including:

a substrate 301 of a first conduction type, i.e., N-type;

a N-type first epitaxial layer 302 of a resistivity 5-20 Ohm·centimeter over the first conduction type, i.e., N-type substrate 301;

a N-type second epitaxial layer 303 of a resistivity 2-10 Ohm·centimeter over the N-type first epitaxial layer 302;

two third epitaxial layers 304 of a second conduction type, i.e., P-type and extending from the upper surface of the second epitaxial layer 303 to the bottom of the second epitaxial layer 303, the two third epitaxial layers are disposed with an interval;

a N-type fourth epitaxial layer 305 generated over the N-type second epitaxial layer 303; and

two P-type well regions 306 implanted from an upper surface of the fourth epitaxial layer 305 with a photoresist as a barrier layer, and connected with the third epitaxial layers 304.

In addition, the VDMOS device in the present embodiment may further include: a drain metal layer 311 under the first conduction type substrate 301; a first source region 313 and a second source region 313 of the first conduction type, over the two P-type well regions 306, and a source metal layer 307 on the surface of the first source region 313 and the second source region 313; a gate region 308 between the first source region 313 and the second source region 313 and over the fourth epitaxial layer 305, and a gate metal layer 310 on the upper surface of the gate region 308.

It is to be noted that the N-type VDMOS device is described above as an example to explain the specific structure and doping types of the present invention, while essentially, the VDMOS device structure disclosed in the present invention also applies to a P-type VDMOS device. That is, the first conduction type may be N-type, the second conduction type may be P-type; alternatively, the first conduction type may be P-type and the second conduction type may be N-type.

For the N-type shallow-trench semi-super-junction VDMOS device provided in the present embodiment, it can be known that the P-type third epitaxial layer 304 and the P-type well over it are connected to form a P-type pillar that is much shallower than that of a conventional super-junction device structure. Therefore, it is called a semi-super-junction. The semi-super-junction device structure may enhance the strength of electric field per unit area, i.e., enhance the voltage endurance capability, which allows the use of lower resistance epitaxial doping and greatly reduces the conduction resistance.

Subjecting the N-type shallow-trench semi-super-junction VDMOS of the present embodiment to laboratory test and compared to a conventional DMOS, the following data comparison table may be obtained, wherein BV is the breakdown voltage of the device, Rsp is the conduction resistance per unit area and Vth is the threshold voltage.

| | BV/V | Rsp/Ω · cm² | Vth/V |
|---|---|---|---|
| Conventional DMOS | 667 | 82.5 | 3.2 |
| Shallow-trench semi-super- | 665 | 58.1 | 3.3 |
| junction VDMOS | | | |

It can be seen clearly from the above-mentioned table that, as compared to the conventional DMOS, the N-type shallow-trench semi-super-junction VDMOS device provided in the embodiment of the present invention reduces the forward conduction resistance drastically.

The characteristics of a semi-super-junction device are between a conventional super-junction and a conventional planar high voltage DMOS. Although the conduction resistance per unit area of the semi-super-junction is larger than that of the super-junction, it's obviously lower than that of a conventional planar device by 30-40%. Further, the characteristics of body diode for the semi-super-junction are relatively close to that for a conventional DMOS, which are advantages over the super-junction. After introducing the semi-super-junction, according to the charge balance principle of the super-junction, compared to the conventional planar DMOS, the JFET region between P-type pillars may achieve the same breakdown voltage with a N-type material of a lower resistivity. Therefore, the resistance per unit area will be much lower than a conventional planer DMOS.

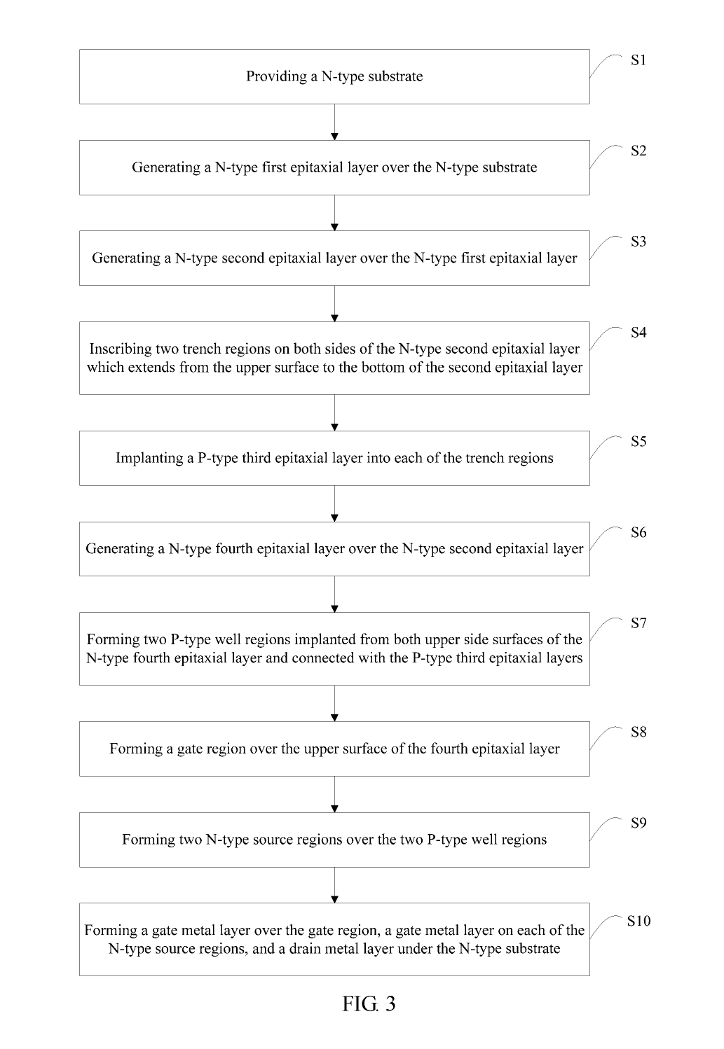

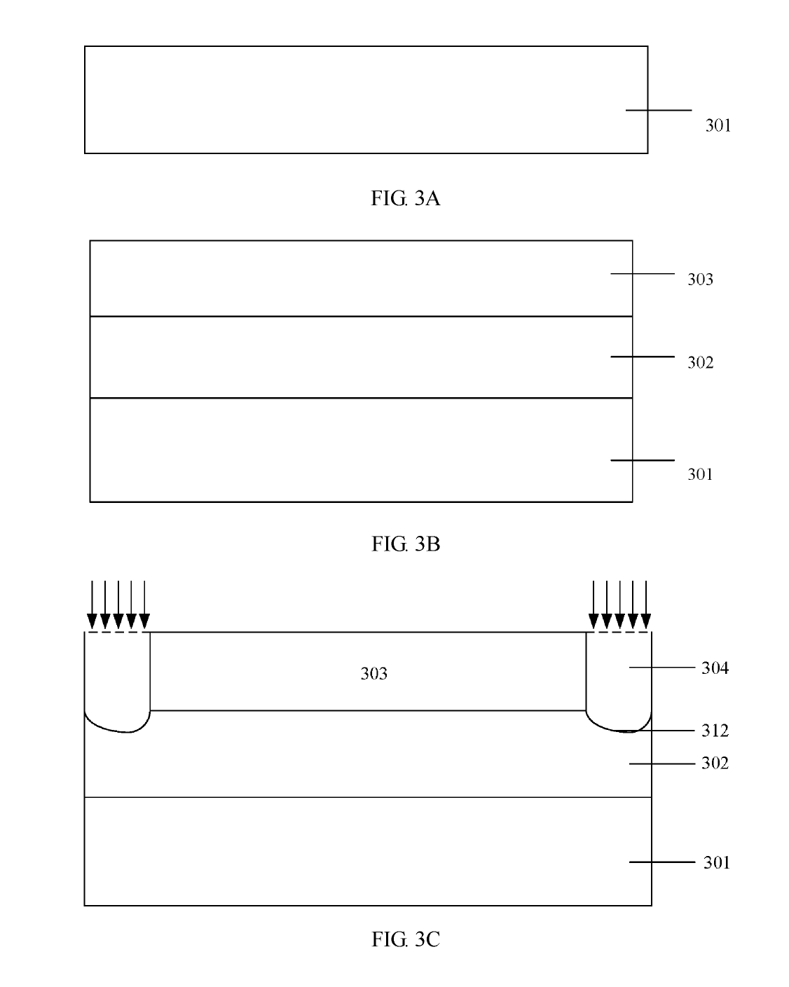

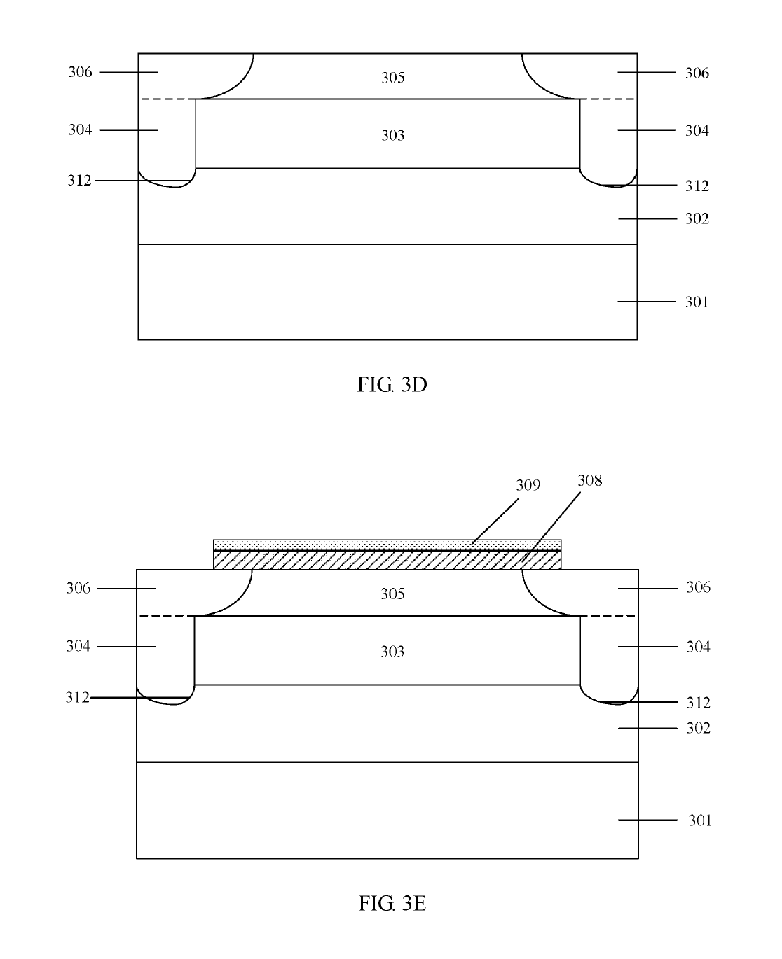

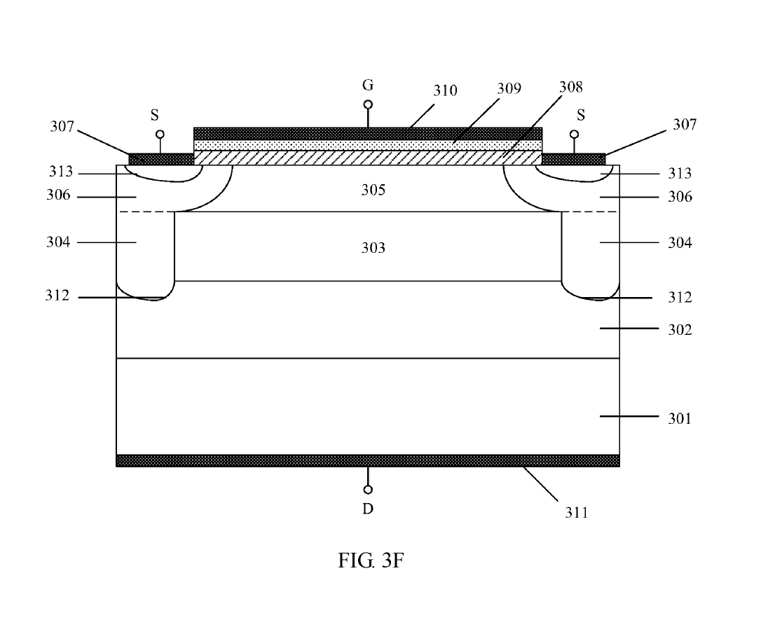

According to another embodiment of the present invention, a manufacturing method of the semi-super-junction VDMOS device is disclosed. FIG. 3 is a flow chart of the manufacturing method of the shallow-trench semi-super-junction VDMOS device. FIGS. 3A-3F are sectional views of the shallow-trench semi-super-junction VDMOS device in steps of the method. The present embodiment is explained only with respect to a N-type shallow-trench semi-super-junction VDMOS device as an example and in connection with the flow chart and the sectional views of steps.

In step S1, a N-type substrate 301 is provided.

Referring to FIG. 3A, in the present embodiment, a monocrystal silicon wafer is heavily doped with N-type ions to form a N-type semiconductor substrate. Wherein, the N-type ions may be phosphor or arsenic.

In step S2, a N-type first epitaxial layer 302 is generated over the N-type substrate.

In step S3, a N-type second epitaxial layer 303 is generated over the N-type first epitaxial layer 302.

Referring to FIG. 3B, in the present embodiment, the N-type monocrystal silicon layer is epitaxially formed over the N-type substrate to form the N-type first epitaxial layer 302 with an epitaxial method. The doping ions for the first epitaxial layer may be the same as that in the N-type substrate. Optionally, the resistivity of the first epitaxial layer may be 5-20 Ohm·centimeter. As above, it is possible to form the N-type second epitaxial layer 303 over the above-mentioned first epitaxial layer 302 and the resultant resistivity of the N-type second epitaxial layer may be 2-10 Ohm·centimeter.

In step S4, two trench regions 312 are inscribed on both sides of the N-type second epitaxial layer 303, such that the two trench regions 312 are extending from the upper surface of the second epitaxial layer to the bottom of the second epitaxial layer.

In step S5, a P-type third epitaxial layer 304 is implanted into each of the above-mentioned trench regions 312.

Referring to FIG. 3C, in the embodiment of the present invention, two trenches 312 are inscribed on the formed N-type second epitaxial layer 303. The width of the trenches is about 0-10 μm and the depth of the trenches is about 0-30 μm. In the embodiment provided in the present invention, the P-type epitaxial layers 304 are implanted into the two formed trenches with ion implantation. When a part of the third epitaxial layers 304 formed in one of the trenches is beyond the second epitaxial layer 303, a chemical mechanical polishing or chemical etching may be subjected to this part, and thus the P-type epitaxial layers remain in the trenches. For example, the upper surface of the second epitaxial layer 303 may be flush with the upper surfaces of the third epitaxial layers 304. The P-type ions implanted in the present step may be boron or indium.

In step S6, a N-type fourth epitaxial layer 305 is formed on the upper surface of the N-type second epitaxial layer 303.

In step S7, two P-type well regions 306 are implanted on both sides of the upper surface of the N-type fourth epitaxial layer 305 and connected with the third epitaxial layers 304 in the two trench regions 312.

Referring to FIG. 3D, in the embodiment provided in the present invention, the N-type fourth epitaxial layer 305 is first formed on the upper surface of the above-mentioned N-type second epitaxial layer 303 and the resultant resistivity of the N-type fourth epitaxial layer 305 is about 2-10 Ohm·centimeter. By using a photoresist as a barrier layer on the N-type fourth epitaxial layer 305 and implanting P-type ions from the surface of the N-type fourth epitaxial layer and over the P-type third epitaxial layers 304 in the trenches, two P-type wells 306 may be formed after a thermal annealing. The P-type wells 306 are connected with the P-type regions in the trenches.

In step S8, a gate region 308 is formed on the surface of the fourth epitaxial layer 305.

Referring to FIG. 3E, in the present embodiment, a gate oxide layer 308 is grown once over the fourth epitaxial layer 305. The gate oxide layer 308 includes at least silicon oxide and contacts the P-type well regions at two ends of the bottom surface. A polycrystalline silicon layer 309 is deposited over the gate oxide layer 308. The polycrystalline silicon layer 309 may be formed with low-pressure chemical vapor deposition. A photoresist layer with a gate region pattern may be formed on the surface of the polycrystalline silicon layer with photolithographic process. By using the photoresist layer with the gate region pattern as a mask, the polycrystalline silicon layer uncovered by the photoresist layer and the gate oxide layer 308 under it are both etched out with dry etching. According to an example, the photoresist layer may be remained temporarily.

In step S9, two N-type source regions, namely the first source region 313 and the second source region 313 are formed over the two P-type well regions 306.

In step S10, a gate metal layer 310 is formed over the above-mentioned gate region 308, a source metal layer 307 is formed over each of the two N-type source regions 313, and a drain metal layer 311 is formed under the N-type substrate 301.

With reference to FIG. 3F, in the present embodiment, metal layers are deposited on the upper surface and the back surface of the device. The method for forming the metal layers may be metallic chemical vapor deposition. The metal layer formed over the polycrystalline silicon layer 309 is the gate metal layer 310, the metal layer formed over the N-type source region 313 is the source metal layer 307, and the metal layer formed on the back surface of the N-type substrate 301 is the drain metal layer 311. The gate region 308 and the gate metal layer 310 constitute the gate G, the first source region 313, the second source region 313 and the source metal layer 307 constitute the source S, and the N-type substrate 301 and the drain metal layer 311 constitute the drain D.

It is to be noted that, the substrate in the present embodiment may include semiconductor elements such as monocrystal, polycrystal or amorphous silicon or silicon germanium (SiGe), or include a hybrid semiconductor structure such as silicon carbide, indium antimonide, lead telluride, indium arsenide, gallium arsenide or gallium antimonide, alloy semiconductor or combinations thereof; or may be silicon on insulator (SOI). Furthermore, the semiconductor substrate may further include other materials such as a multilayer structure comprising epitaxial layers or buried layers. Although several examples of the material that can form the substrate are described herein, any kinds of material that may function as the semiconductor substrate fall into the spirit and scope of the present invention.

The present embodiment discloses the manufacturing method of the shallow-trench semi-super-junction VDMOS device. In summary, a shallow trench structure is introduced into a conventional VDMOS device. For the present embodiment specifically, a shallow trench 312 is inscribed on the N-type epitaxial layer 303, and a P-type epitaxial layer 304 of a proper resistivity is filled in the shallow trench 312 with ion implantation or other means. In order to ensure that the P-type epitaxial layer 304 remains in the shallow trench, chemical mechanical polishing (CMP) or chemical etching may be performed on the surface of the trench. A N-type fourth epitaxial layer 305 is then formed on the N-type second epitaxial layer 303, and a P-type well 306 is formed by ions implantation. After a thermal process, the P-type well is connected with the P-type epitaxial layer in the above-mentioned trench, thereby generating a semi-super-junction.

The above described embodiments are only preferred embodiments of the present invention rather than limiting the present invention in any form.

Although the present invention has been disclosed above with respect to preferred embodiments, they are not intended to limit the present invention. Any one skilled in the art can make many variations and modifications to the technical solution of the present invention with the disclosed contents of the above method and technology or modify them as equivalent embodiments with equivalent variations without departing from the scope of the technical solution of the present invention. Therefore, any simple changes, equivalent variations and modifications made to the above embodiments according to the technical spirit of the present invention without departing from the contents of the technical solution of the present invention will fall into the scope of the technical solution of the present invention.

1. A shallow-trench semi-super-junction Vertical Double-diffused Metal Oxide Semiconductor (VDMOS) device, comprises:
a substrate of a first conduction type;
a first epitaxial layer over the substrate of the first conduction type, wherein the first epitaxial layer has a same conduction type with the substrate of the first conduction type;
a second epitaxial layer over the first epitaxial layer, wherein the second epitaxial layer has a same conduction type with the first epitaxial layer;
two third epitaxial layers extending from an upper surface of the second epitaxial layer to a bottom of the second epitaxial layer, wherein the two third epitaxial layers are disposed with an interval and have a conduction type opposite to that of the second epitaxial layer;
a fourth epitaxial layer over the second epitaxial layer, wherein the fourth epitaxial layer has a same conduction type with the second epitaxial layer;
two well regions implanted from an upper surface of the fourth epitaxial layer and connected with the two third epitaxial layers, wherein the well regions have a same conduction type with the third epitaxial layers;
a first source region and a second source region of the first conduction type over the two well regions,
a source metal layer on an upper surface of the first source region and the second source region;
a drain metal layer under the substrate of the first conduction type;
a gate region between the first source region and the second source region and over the fourth epitaxial layer, and
a gate metal layer on an upper surface of the gate region.

2. The shallow-trench semi-super-junction VDMOS device of claim 1, wherein,
the first epitaxial layer has a resistivity of 5-20 Ohm·centimeter;
the second epitaxial layer has a resistivity of 2-10 Ohm·centimeter;
the third epitaxial layers have a resistivity of 2-10 Ohm·centimeter; and
the fourth epitaxial layer has a resistivity of 2-10 Ohm·centimeter.

3. The shallow-trench semi-super-junction VDMOS device of claim 1, wherein, an upper surface of the second epitaxial layer is flush with an upper surface of the third epitaxial layers.

4. A manufacturing method of a shallow-trench semi-super-junction Vertical Double-diffused Metal Oxide Semiconductor (VDMOS) device, comprises:
providing a substrate of a first conduction type;
forming a first epitaxial layer over the substrate of the first conduction type, wherein the first epitaxial layer has a same conduction type with the substrate of the first conduction type;
forming a second epitaxial layer over the first epitaxial layer, wherein the second epitaxial layer has a same conduction type with the second epitaxial layer;
inscribing two trench regions on an upper surface of the second epitaxial layer, wherein the two trench regions extends from the upper surface of the second epitaxial layer to a bottom of the second epitaxial layer and are disposed with an interval,
forming a third epitaxial layer of a second conduction type in each of the two trench regions, wherein the third epitaxial layers have a conduction type opposite to that of the second epitaxial layer;
forming a fourth epitaxial layer over the second epitaxial layer, wherein the fourth epitaxial layer has a same conduction type with the second epitaxial layer;
forming two well regions which are implanted from an upper surface of the fourth epitaxial layer and connected with the two third epitaxial layers in the trench regions, wherein the well regions have a same conduction type with the third epitaxial layers;
forming a first source region and a second source region of the first conduction type over the two well regions;
forming a gate region between the first source region and the second source region and over the fourth epitaxial layer; and
forming a drain metal layer under the substrate of the first conduction type;
forming a gate metal layer over the gate region;
forming a source metal layer over the first source region and the second source region.

5. The manufacturing method of the shallow-trench semi-super-junction VDMOS device of claim 4, wherein,
the first epitaxial layer has a resistivity of 5-20 Ohm·centimeter;
the second epitaxial layer has a resistivity of 2-10 Ohm·centimeter;
the third epitaxial layers in the trench regions have a resistivity of 2-10 Ohm·centimeter; and
the fourth epitaxial layer has a resistivity of 2-10 Ohm·centimeter.

6. The manufacturing method of the shallow-trench semi-super-junction VDMOS device of claim 4, wherein, the trench regions have a width of 0-10 μm and a depth of 0-30 μm.

7. The manufacturing method of the shallow-trench semi-super-junction VDMOS device of claim 4, wherein, in a case that a part of any one of the third epitaxial layers formed in the trench regions is beyond an upper surface of the second epitaxial layer, this part is subject to chemical mechanical polishing or chemical etching, such that the upper surface of the second epitaxial layer is flush with the upper surface of the third epitaxial layers.

8. The manufacturing method of the shallow-trench semi-super-junction VDMOS device of claim 4, wherein, forming the two well regions comprises:
implanting impurity ions of a same conduction type with the trench regions over the trench regions by using a photoresist as a barrier layer on the fourth epitaxial layer; and
performing thermally annealing to form the well regions.
